(19) United States
(12) Patent Application Publication
(10) Pub. No.: US 2023/0336146 A1
(43) Pub. Date: Oct. 19, 2023

(54) ACOUSTIC WAVE DEVICE WITH AMORPHOUS SILICON OXYCARBIDE LAYER

(71) Applicant: Skyworks Solutions, Inc., Irvine, CA (US)

(72) Inventors: David Albert Feld, Los Altos, CA (US); Michael David Hill, Emmitsburg, MD (US); Benjamin Paul Abbott, Irvine, CA (US); Cedric Olivier Poirel, Munich (DE); Rei Goto, Osaka-Shi (JP)

(21) Appl. No.: 18/299,616

(22) Filed: Apr. 12, 2023

Related U.S. Application Data
(60) Provisional application No. 63/363,011, filed on Apr. 14, 2022.
(60) Provisional application No. 63/363,012, filed on Apr. 14, 2022.

(51) Int. Cl. H03H 9/02

(52) U.S. Cl. CPC H03H 9/02834; H03H 9/02102

(57) ABSTRACT

Aspects of this disclosure relate to an acoustic wave device with a temperature compensation layer that includes silicon oxycarbide. The temperature compensation layer can be in physical contact with at least a portion of a piezoelectric layer of the acoustic wave device. The acoustic wave device can be a surface acoustic wave device in certain applications. The acoustic wave device can be a bulk acoustic wave device in some other applications. Related acoustic wave filters, radio frequency modules, wireless communication devices, and methods are disclosed.

### CROSS REFERENCE TO PRIORITY APPLICATIONS

Any and all applications for which a foreign or domestic priority claim is identified in the Application Data Sheet as filed with the present application are hereby incorporated by reference under 37 C.F.R. § 1.57. This application claims the benefit of priority of U.S. Provisional Application No. 63/363,011, filed Apr. 14, 2022 and titled “ACOUSTIC WAVE DEVICE WITH AMORPHOUS SILICON OXYCARBIDE LAYER,” and U.S. Provisional Application No. 63/363,012, filed Apr. 14, 2022 and titled “ACOUSTIC WAVE DEVICE INCLUDING SILICON OXYCARBIDE LAYER,” the disclosures of each of which are hereby incorporated by reference in their entireties and for all purposes.

### BACKGROUND

### Technical Field

The disclosed technology relates to acoustic wave devices. Embodiments of this disclosure relate to acoustic wave devices with a silicon oxycarbide layer.

### Description of Related Technology

An acoustic wave filter can include a plurality of acoustic wave resonators arranged to filter a radio frequency signal. Example acoustic wave resonators include surface acoustic wave (SAW) resonators and bulk acoustic wave (BAW) resonators. A SAW resonator can include an interdigital transductor electrode on a piezoelectric substrate. The SAW resonator can generate a surface acoustic wave on a surface of the piezoelectric layer on which the interdigital transductor electrode is disposed. In BAW resonators, acoustic waves propagate in a bulk of a piezoelectric layer. Example BAW resonators include film bulk acoustic wave resonators (FBARs) and BAW solidly mounted resonators (SMRs).

Acoustic wave filters can be implemented in radio frequency electronic systems. For instance, filters in a radio frequency front end of a mobile phone can include acoustic wave filters. An acoustic wave filter can be a band pass filter. A plurality of acoustic wave filters can be arranged as a multiplexer. For example, two acoustic wave filters can be arranged as a duplexer.

In acoustic wave devices, temperature compensation can be desirable. For example, temperature compensated SAW (TCSAW) devices typically include a temperature compensation layer, such as a silicon dioxide layer, over and in contact with an interdigital transducer (IDT) electrode.

### SUMMARY OF CERTAIN INVENTIVE ASPECTS

The innovations described in the claims each have several aspects, no single one of which is solely responsible for its desirable attributes. Without limiting the scope of the claims, some prominent features of this disclosure will now be briefly described.

One aspect of this disclosure is an acoustic wave device with temperature compensation. The acoustic wave device includes a piezoelectric layer, an electrode, and a temperature compensation layer including amorphous silicon oxycarbide. The temperature compensation layer is in physical contact with at least a portion of the piezoelectric layer. The acoustic wave device is configured to generate an acoustic wave.

The temperature compensation layer can include a dopant in the amorphous silicon oxycarbide. The amorphous silicon oxycarbide can have a stoichiometric formula of SiO₂(1-Z)C_{Z} in which 0<Z<1. The amorphous silicon oxycarbide can have a stoichiometric formula of SiO_{2(1-Z)}C_{Z}+yC_{free} in which 0<Z<1, 0<y<0.5, and C_{free} is elemental carbon.

The electrode can be an interdigital transducer electrode. The acoustic wave can be a surface acoustic wave.

The acoustic wave device can further include a support substrate under the piezoelectric layer.

The acoustic wave device can further include a second electrode. The piezoelectric layer can be positioned between the electrode and the second electrode. The acoustic wave can be a bulk acoustic wave. The temperature compensation layer can be positioned between the electrode and the piezoelectric layer. The acoustic wave device can further include an air cavity, and the acoustic wave device can be a film bulk acoustic wave resonator.

Another aspect of this disclosure is an acoustic wave device that includes a piezoelectric layer, an interdigital transducer electrode on the piezoelectric layer, and an amorphous silicon oxycarbide layer. The acoustic wave device is configured to generate an acoustic wave.

The amorphous silicon oxycarbide layer can include a dopant.

The amorphous silicon oxycarbide can have a stoichiometric formula of SiO_{2(1-Z)}C_{Z} in which 0<Z<1. The amorphous silicon oxycarbide can have a stoichiometric formula of SiO_{2(1-Z)}C_{Z} in which 0<Z<1, 0<y<0.5, and C_{free} is elemental carbon.

The amorphous silicon oxycarbide layer can be positioned over and in physical contact with the interdigital transducer electrode.

The acoustic wave device can further include a support substrate. The amorphous silicon oxycarbide layer can be positioned between the piezoelectric layer and the support substrate. The amorphous silicon oxycarbide layer can be in physical contact with the piezoelectric layer. The acoustic wave device can further include an intervening layer positioned between the support substrate and the amorphous silicon oxycarbide layer. The acoustic wave device can further include a second amorphous silicon oxycarbide layer positioned over and in physical contact with the interdigital transducer electrode.

Another aspect of this disclosure is an acoustic wave device that includes a trap rich layer over a substrate, the substrate including a semiconductor; an amorphous silicon oxycarbide layer over the trap rich layer; a piezoelectric layer over the amorphous silicon oxycarbide layer; and an electrode over the piezoelectric layer. The acoustic wave device is configured to generate an acoustic wave.

The amorphous silicon oxycarbide layer can include a dopant in the amorphous silicon oxycarbide.

Material of the amorphous silicon oxycarbide can have a stoichiometric formula of SiO_{2(1-Z)}C_{Z} in which 0<Z<1. Material of the amorphous silicon oxycarbide can have a stoichiometric formula of SiO_{2(1-Z)}C_{Z}+C_{free} in which 0<Z<1, 0<y<0.5, and C_{free} is elemental carbon.

The semiconductor can be silicon.

The electrode can be an interdigital transducer electrode. The acoustic wave can be a surface acoustic wave. The acoustic wave device can further include an intervening layer positioned between the amorphous silicon oxycarbide layer and the piezoelectric layer. The acoustic wave device can further include a temperature compensation layer over and in physical contact with the interdigital transducer electrode. The temperature compensation layer can include silicon oxycarbide.

The acoustic wave device can further include a second electrode. The piezoelectric layer can be positioned between the electrode and the second electrode. The acoustic wave can be a bulk acoustic wave.

The acoustic wave device can further include a second electrode and an air cavity. The piezoelectric layer can be positioned between the electrode and the second electrode. The second electrode and the amorphous silicon oxycarbide layer can be on opposing sides of the air cavity.

Another aspect of this disclosure is a film bulk acoustic wave resonator that includes a support substrate, a trap rich layer over the support substrate, an air cavity, and an amorphous silicon oxycarbide layer positioned between the trap rich layer and the air cavity. The film bulk acoustic wave resonator is configured to generate a bulk acoustic wave.

The support substrate can be a silicon substrate.

The amorphous silicon oxycarbide layer can include a dopant. The amorphous silicon oxycarbide layer can include free carbon.

Material of the amorphous silicon oxycarbide can have a stoichiometric formula of SiO_{2(1-Z)}C_{Z} in which 0<Z<1. Material of the amorphous silicon oxycarbide can have a stoichiometric formula of SiO_{2(1-Z)}C_{Z}+C_{free} in which 0<Z<1, 0<y<0.5, and C_{free} is elemental carbon.

Another aspect of this disclosure is a bulk acoustic wave device comprising that includes a piezoelectric layer, electrodes on opposing sides of the piezoelectric layer, and an amorphous silicon oxycarbide layer positioned between the electrodes. The bulk acoustic wave device is configured to generate a bulk acoustic wave.

The amorphous silicon oxycarbide layer can be positioned between one of the electrodes and the piezoelectric layer. The amorphous silicon oxycarbide layer can be in physical contact with the piezoelectric layer.

The bulk acoustic wave device can further include an air cavity, a support substrate, and a trap rich layer on the support substrate. A second amorphous silicon oxycarbide layer can be positioned between the air cavity and the trap rich layer.

The amorphous silicon oxycarbide layer can include a dopant. The amorphous silicon oxycarbide layer can include free carbon.

Material of the amorphous silicon oxycarbide can have a stoichiometric formula of SiO_{2(1-Z)}C_{Z} in which 0<Z<1. Material of the amorphous silicon oxycarbide can have a stoichiometric formula of SiO_{2(1-Z)}C_{Z}+yC_{free} in which 0<Z<1, 0<y<0.5, and C_{free} is elemental carbon.

Another aspect of this disclosure is an acoustic wave filter that includes an acoustic wave device in accordance with any suitable principles and advantages disclosed herein and a plurality of additional acoustic wave devices. The acoustic wave filter is configured to filter a radio frequency signal.

Another aspect of this disclosure is a radio frequency module that includes an acoustic wave filter and radio frequency circuitry coupled to the radio frequency filter. The acoustic wave filter that includes an acoustic wave device in accordance with any suitable principles and advantages disclosed herein. The acoustic wave filter and the radio frequency circuitry are enclosed within a common package.

Another aspect of this disclosure is a wireless communication device that includes an acoustic wave filter, an antenna operatively coupled to the acoustic wave filter, a radio frequency amplifier operatively coupled to the acoustic wave filter and configured to amplify a radio frequency signal, and a transceiver in communication with the radio frequency amplifier. The acoustic wave filter that includes an acoustic wave device in accordance with any suitable principles and advantages disclosed herein.

Another aspect of this disclosure is a method of filtering a radio frequency signal, the method includes receiving a radio frequency signal at a port of an acoustic wave filter that includes an acoustic wave device in accordance with any suitable principles and advantages disclosed herein; and filtering the radio frequency signal with the acoustic wave filter.

For purposes of summarizing the disclosure, certain aspects, advantages and novel features of the innovations have been described herein. It is to be understood that not necessarily all such advantages may be achieved in accordance with any particular embodiment. Thus, the innovations may be embodied or carried out in a manner that achieves or optimizes one advantage or group of advantages as taught herein without necessarily achieving other advantages as may be taught or suggested herein.

The present disclosure relates to U.S. patent application Ser. No. ______ [Attorney Docket SKYWRKS.1323A2], titled “ACOUSTIC WAVE DEVICE INCLUDING SILICON OXYCARBIDE LAYER,” filed on even date herewith, the entire disclosure of which is hereby incorporated by reference herein.

### BRIEF DESCRIPTION OF THE DRAWINGS

Embodiments of this disclosure will now be described, by way of non-limiting example, with reference to the accompanying drawings.

FIG. 1A is a top view of an interdigital transducer (IDT) electrode of a temperature compensated surface acoustic wave (TCSAW) device according to an embodiment. FIG. 1B is a cross-sectional view of the TCSAW device of FIG. 1A.

FIGS. 2, 3, and 4 are cross-sectional views of multilayer piezoelectric substrate (MPS) SAW devices according to embodiments.

FIG. 5A is a cross-sectional diagram of a bulk acoustic wave (BAW) device according to an embodiment. FIG. 5B is an example plan view of the BAW device of FIG. 5A.

FIG. 6 is a cross-sectional diagram of a BAW device according to an embodiment.

FIGS. 7 and 8 are cross-sectional views of portions of temperature compensated BAW (TCBAW) devices according to embodiments.

FIG. 9A is a schematic diagram of a ladder filter that includes an acoustic wave resonator according to an embodiment. FIG. 9B is schematic diagram of an acoustic wave filter.

FIGS. 10A, 10B, 10C, and 10D are schematic diagrams of multiplexers that includes an acoustic wave resonator according to an embodiment.

FIGS. 11, 12, and 13 are schematic block diagrams of modules that include a filter with an acoustic wave device according to an embodiment.

FIG. 14 is a schematic block diagram of a wireless communication device that includes a filter with an acoustic wave device according to an embodiment.

### DETAILED DESCRIPTION OF CERTAIN EMBODIMENTS

The following description of certain embodiments presents various descriptions of specific embodiments. However, the innovations described herein can be embodied in a multitude of different ways, for example, as defined and covered by the claims. In this description, reference is made to the drawings where like reference numerals can indicate identical or functionally similar elements. It will be understood that elements illustrated in the figures are not necessarily drawn to scale. Moreover, it will be understood that certain embodiments can include more elements than illustrated in a drawing and/or a subset of the elements illustrated in a drawing. Further, some embodiments can incorporate any suitable combination of features from two or more drawings. Any suitable principles and advantages of the embodiments disclosed herein can be implemented together with each other.

Acoustic wave devices can include a temperature compensation layer. Such a temperature compensation layer can bring the temperature coefficient of frequency (TCF) of an acoustic wave device closer to zero relative to a similar acoustic wave device without the temperature compensation layer. The temperature compensation layer can have a positive TCF. This can compensate for a piezoelectric layer of the acoustic wave device having a negative TCF. The temperature compensation layer can be in physical contact with at least a portion of the piezoelectric layer of an acoustic wave device. The temperature compensation layer can be in physical contact with an electrode of an acoustic wave device. Certain surface acoustic wave (SAW) devices include a temperature compensation layer over and in physical contact with an interdigital transducer (IDT) electrode. Such SAW devices can be referred to as temperature compensated SAW (TCSAW) devices.

A silicon dioxide (SiO₂) layer is used as a temperature compensation layer for an acoustic wave device in a variety of different applications. Such a silicon dioxide layer can also be referred to as amorphous silica or fused silica in various applications. Silicon dioxide is a material with an acoustic velocity and an elastic modulus that increase with temperature. This can allow for temperature compensation with piezoelectric materials that have an acoustic velocity and an elastic modulus that decrease with temperature.

A technical challenge with amorphous silicon dioxide is that it can have a relatively low fracture toughness. With a relatively low fracture toughness, cracking can occur in applications that involve relatively high power levels.

Silicon oxycarbide glass has a higher fracture toughness, hardness, and modulus of rupture than amorphous silicon dioxide. At the same time, silicon oxycarbide glass also has a positive temperature coefficient of elastic modulus and acoustic velocity. Silicon oxycarbide glass can be an excellent technical solution for temperature compensated acoustic wave devices at relatively high power levels. Accordingly, amorphous silicon oxycarbide can be used for a temperature compensation layer in acoustic wave devices. As one example, a TCSAW device can include a temperature compensation layer that includes amorphous silicon oxycarbide. As another example, a bulk acoustic wave (BAW) device can include a temperature compensation layer that includes amorphous silicon oxycarbide.

An amorphous silicon oxycarbide layer can alternatively or additionally be included over a trap rich layer in an acoustic wave device. For example, an amorphous silicon oxycarbide layer can be included over a trap rich layer that is positioned on a semiconductor substrate of a BAW device. An air cavity can be positioned over the amorphous silicon oxycarbide layer in such a BAW device. As another example, an amorphous silicon oxycarbide layer can be included over a trap rich layer of a multilayer piezoelectric substrate (MPS) SAW device. Amorphous silicon dioxide has been included over a trap rich layer in certain acoustic wave devices. Amorphous silicon oxycarbide advantageously has higher thermal conductivity relative to amorphous silicon dioxide and can reduce parasitic surface conduction relative to a silicon dioxide-silicon interface. Amorphous silicon oxycarbide can provide relatively good electrical insulation that can be advantageous over the trap rich layer.

Amorphous silicon oxycarbide can replace any silicon dioxide layer of an acoustic wave device as suitable. In certain applications, an acoustic wave device can include a plurality of amorphous silicon oxycarbide layers in place of silicon dioxide layers of previous acoustic wave devices.

Aspects of this disclosure relate to including a dense silicon oxycarbide glass with the stoichiometric formula of SiO_{2(1-Z)}C_{Z} with 0<Z<1 in an acoustic wave device. The silicon oxycarbide can have a formula of SiO_{2(1-Z)}C_{Z} with 0<Z<0.75. For silicon oxycarbide with a formula of SiO_{2(1-Z)}C_{Z}, the upper bound of the Z range can be a highest Z value where the silicon oxycarbide remains amorphous. The silicon oxycarbide glass has a positive TCF. The silicon oxycarbide can be with or without second phase graphite or hydrogen produced by chemical vapor deposition (CVD) or physical vapor deposition (PVD). The silicon oxycarbide layer can be implemented in place of a silicon dioxide layer in an acoustic wave device for a temperature compensation layer and/or over a trap rich layer. In certain applications, the silicon oxycarbide layer can be a temperature compensation layer for a TCSAW or a temperature compensated BAW (TCBAW) device. In such applications, a silicon oxycarbide glass can have desirable mechanical properties, such as the modulus of rupture, fracture toughness, and hardness, for improved acoustic loss properties relative to silicon dioxide. In some applications, the silicon oxycarbide layer can be over a trap rich layer on a semiconductor substrate, such as a silicon substrate. Amorphous silicon oxycarbide has higher thermal conductivity relative to amorphous silicon dioxide for such applications. At the same time, amorphous silicon oxycarbide can provide desirable electrical insulation. In addition, amorphous silicon oxycarbide can reduce parasitic surface conduction at an interface with silicon relative to silicon dioxide.

Properties of amorphous silicon oxycarbide will now be discussed. Silicon oxycarbide can be referred to as Si—O—C in certain instances. As used herein, the terms amorphous silicon oxycarbide and silicon oxycarbide glass are interchangeable.

Amorphous silicon oxycarbide typically has a higher density than amorphous silicon dioxide. For example, in certain applications, amorphous silicon oxycarbide can have a density of 2.35 grams per cubic centimeter (g/cc) and amorphous silicon dioxide can have a density of 2.20 g/cc. The density of amorphous silicon oxycarbide can vary based on the Z value and on processing. The density of amorphous silicon oxycarbide can depend on annealing and/or an amount of free carbon. Annealing can increase the density of silicon oxycarbide. In certain instances, annealing at a higher temperature can increase the density of silicon oxycarbide more than annealing at a lower temperature.

The mechanical properties of silicon oxycarbide glass can be better than mechanical properties of silicon dioxide for acoustic wave devices. The modulus of rupture (MOR), elastic modulus (E), and Vickers hardness (H) can be improved by using silicon oxycarbide glass relative to silicon dioxide in certain acoustic wave devices. Fused silicon dioxide can have a hardness of 9.3 gigapascal (GPa) and silicon oxycarbide can have a hardness of 11.4 GPa. Silicon dioxide can have a fracture toughness of 1.0 MPa·m^{1/2} and silicon oxycarbide can have a fracture toughness of 1.8 MPa·m^{1/2}. Silicon dioxide can have a Young's elastic modulus of 70 GPa and silicon oxycarbide can have a Young's elastic modulus of 97.9 GPa. These improved mechanical properties can reduce or eliminate mechanical failures in TCSAW devices that have amorphous silicon oxycarbide temperature compensation layers. As an example, a thermal shock induced crack in a silicon dioxide temperature compensation layer of the TCSAW device can develop from a relatively high power operation. Such a crack can be mitigated, avoided, or occur less frequently when using an amorphous silicon oxycarbide temperature compensation layer.

A comparison of certain properties of fused silicon dioxide and silicon oxycarbide is provided in Table 1. An amorphous silicon oxycarbide layer has a positive TCF due to the properties of silicon oxycarbide.

TABLE 1

| | Fused SiO₂ | | SiOC | |
|---|---|---|---|---|
| Density | 2.20 | g/cc | 2.35 | g/cc |
| Elastic Modulus | 70 | GPa | 97.9 | GPa |
| (Young's Modulus) | | | | |
| Acoustic Impedance | 3.92 × 10⁵ | kg/m²s (Ry) | 4.80 × 10⁵ | kg/m²s (Ry) |
| Hardness | 9.3 | GPa | 11.4 | GPa |
| Fracture Toughness | 1.0 | MPa-m^{1/2} | 1.8 | MPa-m^{1/2} |
| Thermal Expansion | 0.5 | ppm/C | 3.14 | ppm/C |

Coefficient

The thermal expansion coefficient of silicon oxycarbide can vary within a range based on the stoichiometric ratio of oxygen and carbon in silicon oxycarbide. The thermal expansion coefficient of silicon oxycarbide can be tailored based on properties of a piezoelectric layer, such as a lithium niobate crystal or a lithium tantalate crystal. This can provide desirable temperature compensation in an acoustic wave device.

The elastic modulus of silicon oxycarbide can increase with temperature. Silicon oxycarbide increases in stiffness as the temperature increases. The rate of change in the elastic modulus over the rate of change of temperature for silicon oxycarbide can be similar to fused silica. Young's modulus is higher for silicon oxycarbide than for amorphous silica.

Amorphous silicon oxycarbide has a higher acoustic impedance than fused silica. The acoustic impedance can be a product of density and acoustic velocity. Amorphous silicon oxycarbide can have an acoustic impedance of 4.80×105 Rydberg units of energy (Ry) and fused silica can have an acoustic impedance of 3.92×105 Ry.

An amorphous silicon oxycarbide layer can have desirable thermal conductivity. The thermal conductivity can be a result of strong covalent bonds. Glass can typically have thermal conductivities that are not particularly desirable. Amorphous silicon oxycarbide can have a higher thermal conductivity than fused silica.

Silicon oxycarbide can have one or more electrical properties that may be slightly less desirable than amorphous silicon dioxide. A comparison of certain electrical properties of amorphous silicon dioxide and silicon oxycarbide is provided in Table 2. The electrical properties of silicon oxycarbide can depend on process parameters and/or temperature.

TABLE 2

| | A-SiO₂ | SiOC |
|---|---|---|
| Conductivity | 10⁻²² ohm-cm | 4 × 10⁻¹³ ohm-cm |
| Dielectric Constant | 4.0 | 4.4 |
| Loss Tangent | 10⁻⁴ | 0.1 |
| (low frequency) | | |

A qualitative comparison of properties of amorphous silicon dioxide and silicon oxycarbide is provided in Table 3. Silicon oxycarbide is likely to have lower acoustic losses than amorphous silicon dioxide due to having higher hardness. The higher dielectric loss for silicon oxycarbide has been measured at a relatively low frequency only.

TABLE 3

| | A-SiO₂ | SiOC |
|---|---|---|
| Density | | Slightly higher |
| Elastic Modulus | | Higher |
| Hardness | | Higher |
| MOR (Fracture Toughness) | | Higher |
| Acoustic Impedance | | Higher |
| Thermal Expansion | | Higher |
| Coefficient | | |
| dE/DT | Similar | Similar |
| Dielectric Constant | | Slightly Higher |
| Electrical Conductivity | | Higher |
| Dielectric Loss | | Higher (at low frequency) |

Silicon oxycarbide glass can include free carbon in some applications. Such silicon oxycarbide glass can have the stoichiometric formula of SiO_{2(1-Z)}C_{Z}+yC_{free}, in which 0<Z<1, 0<y<0.5, and C_{free} is elemental carbon. The silicon oxycarbide glass can have the stoichiometric formula of SiO_{2(1-Z)}C_{Z}+yC_{free}, in which 0<Z<0.75, 0<y<0.5, and C_{free} is elemental carbon. For silicon oxycarbide with a formula of SiO_{2(1-Z)}C_{Z}+yC_{free}, the upper bound of the Z range can be a highest Z value where the silicon oxycarbide remains amorphous. The free carbon can be included in the silicon oxycarbide layer as a result of processing. In certain instances, free carbon can be reduced, minimized, or avoided entirely in forming silicon oxycarbide glass. When no free carbon is present, y equals zero in the preceding formula.

A silicon oxycarbide layer can be doped with any suitable dopant. For example, a silicon oxycarbide layer can be doped with boron (B).

As discussed above, an amorphous silicon oxycarbide layer can be implemented in acoustic wave devices. An amorphous silicon oxycarbide layer can be implemented in a SAW device such as a TCSAW or an MPS SAW device, a BAW device such as a film bulk acoustic wave resonators (FBAR) or a BAW solidly mounted resonator (SMR), a Lamb wave device, a boundary wave resonator, or any other suitable acoustic wave resonator. Example acoustic wave devices will now be discussed.

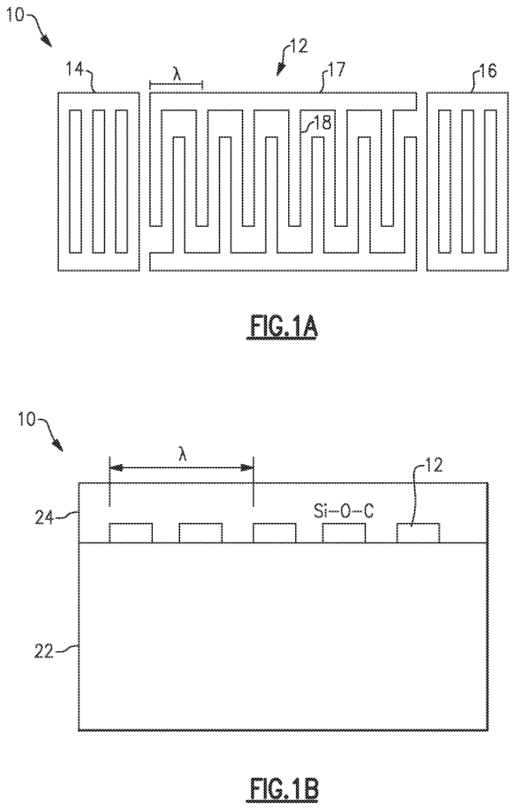

Amorphous silicon oxycarbide layers disclosed herein can be implemented in SAW devices. In TCSAW devices, an amorphous silicon oxycarbide temperature compensation layer over an interdigital transducer (IDT) electrode can have a sufficiently high fracture toughness to reduce or eliminate cracking from high power applications that has occurred with silicon dioxide temperature compensation layers. In MPS SAW devices, an amorphous silicon oxycarbide layer can be overtop a trap rich layer. This can provide higher thermal conductivity relative to amorphous silica and/or reduce parasitic surface conduction at an interface with a silicon substrate. Examples of such SAW device will be discussed with reference to FIGS. 1A to 4.

FIG. 1A is a top view of an interdigital transducer (IDT) electrode 12 of a TCSAW device 10. FIG. 1B is a cross-sectional view of the TCSAW device 10 of FIG. 1A. As shown in FIG. 1A, the IDT electrode 12 is positioned between a first acoustic reflector 14 and a second acoustic reflector 16. The IDT electrode 12 and acoustic reflectors 14 and 16 can be positioned over a common piezoelectric layer. The acoustic reflectors 14 and 16 are separated from the IDT electrode 12 by respective gaps. The IDT electrode 12 includes a bus bar 17 and IDT fingers 18 extending from the bus bar 17. The IDT fingers 18 have a pitch of λ. The TCSAW device 10 can include any suitable number of IDT fingers 18. The pitch λ of the IDT fingers 18 corresponds to wavelength of a surface acoustic wave generated by the TCSAW device 10.

The TCSAW device 10 illustrated in FIG. 1B includes a piezoelectric layer 22, an IDT electrode 12 on the piezoelectric layer 22, and a temperature compensation layer 24 over the IDT electrode 12. The piezoelectric layer 22 can be any suitable piezoelectric layer, such as a lithium niobate layer or a lithium tantalate layer. The piezoelectric layer 22 can have a negative TCF. The IDT electrode 12 can include any suitable material for an electrode, such as tungsten, aluminum, molybdenum, the like, or any suitable combination or alloy thereof. The IDT electrode 12 can include two or more metallic layers in certain applications. The TCSAW device 10 can be included in a filter in accordance with any suitable principles and advantages disclosed herein.

The temperature compensation layer 24 includes amorphous silicon oxycarbide. In some instances, the temperature compensation layer 24 consists or consists essentially of amorphous silicon oxycarbide. The temperature compensation layer 24 can include free carbon and/or any suitable dopant, such as boron, in certain applications. The silicon oxycarbide of the temperature compensation layer 24 can bring the TCF of the TCSAW device 10 closer to zero relative to a similar SAW device without the temperature compensation layer 24. The silicon oxycarbide of the temperature compensation layer 24 can have a positive TCF. This can compensate for the piezoelectric layer 22 having a negative TCF. The temperature compensation layer 24 is in physical contact with at least a portion of the piezoelectric layer 22. The temperature compensation layer 24 is also in physical contact with the IDT electrode 12.

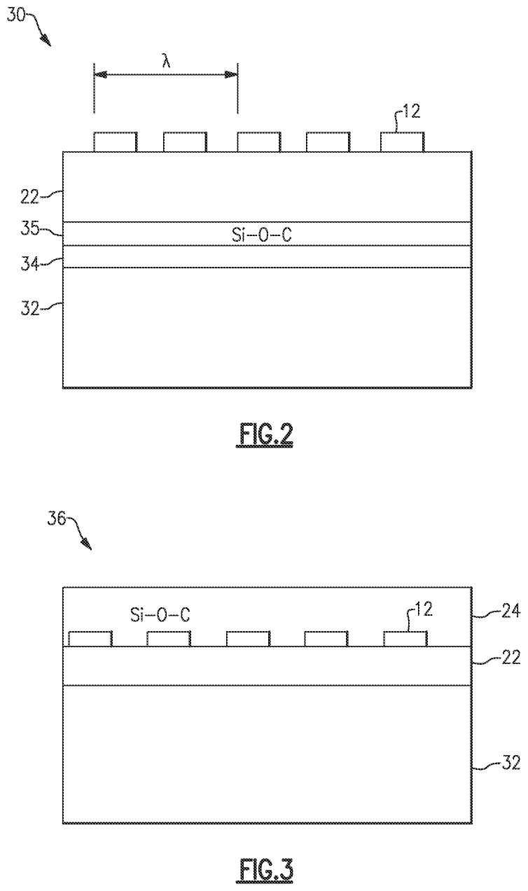

FIG. 2 is a cross-sectional view of an MPS SAW device 30 according to an embodiment. The illustrated MPS SAW device 30 includes a multilayer piezoelectric substrate including a support substrate 32, a trap rich layer 34, an amorphous silicon oxycarbide layer 35, and a piezoelectric layer 22. The MPS SAW device 30 also includes an IDT electrode 12 on the piezoelectric layer 22.

The piezoelectric layer 22 can be a lithium tantalate layer in the MPS SAW device 30. In certain applications, the piezoelectric layer 22 can be thinner in the MPS SAW device 30 compared to in the TCSAW device 10. For example, the piezoelectric layer 22 can have a thickness of less than λ in the MPS SAW device 30, in which λ is a wavelength of a surface acoustic wave generated by the MPS SAW device 30. In some other instances, the piezoelectric layer 22 can have a thickness on the order of 10s of λ, in which λ is a wavelength of a surface acoustic wave generated by the MPS SAW device 30.

The support substrate 32 can be a semiconductor substrate, such as a silicon substrate. The support substrate 32 can be a high resistivity silicon substrate. The support substrate 32 can have a crystalline structure. The trap rich layer 34 can be a polysilicon layer, an amorphous silicon layer, or the like. The trap rich layer 34 can have a reduced carrier mobility relative to the support substrate 32. The trap rich layer 34 can trap free charge carriers to reduce spurious radio frequency current due to electric fields of the MPS SAW device 30.

The amorphous silicon oxycarbide layer 35 can be a buried layer. The amorphous silicon oxycarbide layer 35 is positioned between the trap rich layer 34 and the piezoelectric layer 22 in the MPS SAW device 30. The amorphous silicon oxycarbide layer 35 is in physical contact with the trap rich layer 34 as illustrated in FIG. 2. In some other applications, the amorphous silicon oxycarbide layer can be over a silicon dioxide layer that is over a trap rich layer. More generally, an amorphous silicon oxycarbide layer can be positioned between a support substrate and a piezoelectric layer in an MPS stack. One or more layers can be positioned between an amorphous silicon oxycarbide layer and the support substrate in an MPS SAW stack in certain applications. Alternatively or additionally, one or more layers can be positioned between an amorphous silicon oxycarbide layer and the piezoelectric layer in an MPS SAW stack in certain applications.

FIG. 3 is a cross-sectional view of an MPS SAW device 36 according to another embodiment. In the MPS SAW device 36, a temperature compensation layer 24 that include amorphous silicon oxycarbide is included over the IDT electrode 12. The piezoelectric layer 22 in the MPS SAW device 36 can be a lithium niobate layer. In some instances (not illustrated), on or more intervening layers can be included between the piezoelectric layer 22 and the support substrate 32 in the MPS SAW device 36. Non-limiting examples of a layer of the one or more additional layers include an adhesion layer, a dispersion adjustment layer, and a thermal dissipation layer. In the MPS SAW device 36, the support substrate 32 can be a semiconductor substrate, a silicon substrate, a ceramic substrate, a polycrystalline spinel substrate, a quartz substrate, a sapphire substate, a borosilicate substrate, a glass substrate, or any other suitable substrate. A support substate can include any of these support substrates in other MPS SAW devices and/or BAW devices as suitable.

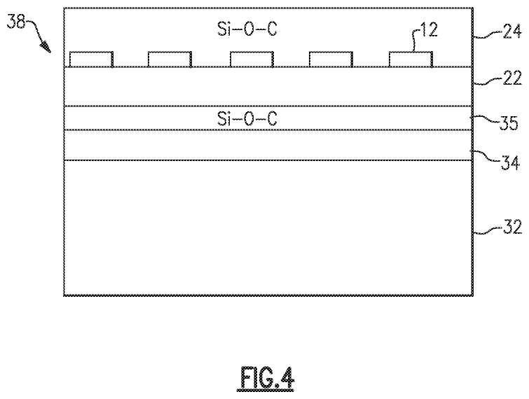

FIG. 4 is a cross-sectional view of an MPS SAW device 38 according to another embodiment. The MPS SAW device 38 includes both (1) a temperature compensation layer 24 that includes amorphous silicon oxycarbide and (2) a silicon oxycarbide layer 35 between a trap rich layer 34 and a piezoelectric layer 22.

An amorphous silicon oxycarbide layer can be implemented in a BAW device. In BAW devices, an amorphous silicon oxycarbide layer can be used over a trap rich layer, as a temperature compensation layer, as a passivation and trim layer, or any suitable combination thereof. BAW resonators, such as FBARs and BAW SMRs, can include one or more amorphous silicon oxycarbide layers in accordance with any suitable principles and advantages disclosed herein. Example BAW resonators will be discussed with reference to FIG. 5A to 8.

FIG. 5A is a cross sectional diagram of a BAW device 50 according to an embodiment. The BAW device 50 includes at least one amorphous silicon oxycarbide layer. As illustrated, the BAW device 50 includes a support substrate 54, a trap rich layer 55, a first passivation layer 56, an air cavity 58, a first electrode 60, a piezoelectric layer 62, a temperature compensation layer 63, a second electrode 64, and a second passivation layer 65. The BAW device 50 also includes a recessed frame structure 67 and a raised frame structure 68.

The support substrate 54 can be a semiconductor substrate, such as a silicon substrate. The support substrate 54 can be a high resistivity silicon substrate. The support substrate 54 can be any other suitable support substrate. The trap rich layer 55 can be a polysilicon layer, an amorphous silicon layer, or the like. The trap rich layer 55 is positioned between the support substrate 54 and the first passivation layer 56. The first passivation layer 56 can be referred to as a lower passivation layer. The first passivation layer 56 can be a buried oxide layer. The first passivation layer 56 can be an amorphous silicon oxycarbide layer in certain applications. In some other applications, the first passivation layer 56 can be a silicon dioxide layer or any other suitable passivation layer, such as aluminum oxide, silicon carbide, aluminum nitride, silicon nitride, silicon oxynitride, or the like. In some instances, a silicon dioxide layer can be over a trap rich layer and an amorphous silicon oxycarbide layer can be over the silicon dioxide layer.

The air cavity 58 is an example of an acoustic reflector. As illustrated in FIG. 5A, the air cavity 58 is located above the support substrate 54. The air cavity 58 is positioned between the support substrate 54 and the first electrode 60. In some applications, an air cavity can be etched into a support substrate. In certain applications, a solid acoustic mirror with alternating high acoustic impedance and low acoustic impedance can be included in place of an air cavity. A BAW device with an air cavity can be referred to as an FBAR. A BAW device with a solid acoustic mirror can be referred to as a BAW SMR.

The first electrode 60 can be referred to as a lower electrode or a bottom electrode. The first electrode 60 can have a relatively high acoustic impedance. The first electrode 60 can include molybdenum (Mo), tungsten (W), ruthenium (Ru), chromium (Cr), iridium (Ir), platinum (Pt), Ir/Pt, or any suitable alloy and/or combination thereof. The second electrode 64 can have a relatively high acoustic impedance. The second electrode 64 can include Mo, W, Ru, Cr, Ir, Pt, Ir/Pt, or any suitable alloy and/or combination thereof. The second electrode 64 can be formed of the same material as the first electrode 60 in certain instances. The second electrode 64 can be referred to as an upper electrode or a top electrode. The thickness of the first electrode 60 can be approximately the same as the thickness of the second electrode 64 in a main acoustically active region of the BAW device 50. The first electrode 60 and the second electrode 64 can be the only electrodes of the BAW device 50.

The piezoelectric layer 62 is positioned between the first electrode 60 and the second electrode 64. The piezoelectric layer 62 can include aluminum nitride or any other suitable piezoelectric material. The piezoelectric layer 62 can be doped with any suitable dopant, such as scandium (Sc), chromium (Cr), magnesium (Mg), sulfur (S), yttrium (Y), silicon (Si), germanium (Ge), oxygen (O), hafnium (Hf), zirconium (Zr), titanium (Ti), or the like. In certain instances, the piezoelectric layer 62 can be an aluminum nitride layer doped with scandium. Doping the piezoelectric layer 62 can adjust resonant frequency. Doping the piezoelectric layer 62 can increase the coupling coefficient k² of the BAW device 50. Doping to increase the coupling coefficient k² can be advantageous at higher frequencies where the coupling coefficient k² can be degraded.

The temperature compensation layer 63 can bring the TCF of the BAW device 63 closer to zero. The temperature compensation layer 63 can have a positive TCF. The temperature compensation layer 63 can be in physical contact with the piezoelectric layer 62. The temperature compensation layer 63 can be in physical contact with an electrode of the BAW device (e.g., the second electrode 64 in FIG. 5A). The temperature compensation layer 63 can include amorphous silicon oxycarbide. As illustrated, the temperature compensation layer 63 is positioned between an electrode of the BAW device 50 (e.g., the second electrode 64 in FIG. 5A) and the piezoelectric layer 62. TC BAW devices can include an amorphous silicon oxycarbide temperature compensation layer (1) between a piezoelectric layer and upper electrode (e.g., as illustrated in FIG. 5A), (2) between the piezoelectric layer and lower electrode, (3) embedded within a piezoelectric layer, (4) embedded within an electrode, or (5) any suitable combination of (1) to (4).

The second passivation layer 65 can be referred to as an upper passivation layer. The second passivation layer 65 can be referred to as a passivation and trimming layer, as the second passivation layer 65 can be used for both passivation and frequency trimming. The second passivation layer 65 can be a silicon oxycarbide layer, a silicon dioxide layer, or any other suitable passivation layer. The second passivation layer 65 can be the same material as the first passivation layer 56 in certain instances. The second passivation layer 65 can have different thicknesses in different regions of the BAW device 50. Part of the second passivation layer 65 can form at least part of the recessed frame structure 67 and/or the raised frame structure 68.

An active region or active domain of the BAW device 50 can be defined by a portion of the piezoelectric layer 62 that overlaps an acoustic reflector, such as the air cavity 58, and is between the first electrode 60 and the second electrode 64. The active region can correspond to where voltage is applied on opposing sides of the piezoelectric layer 62 over the acoustic reflector. The active region can be the acoustically active region of the BAW device 50. The BAW device 50 also includes a recessed frame region with the recessed frame structure 67 in the active region and a raised frame region with the raised frame structure 68 in the active region. The raised frame structure 68 can also include an oxide layer 69 positioned between the piezoelectric layer 62 and an electrode (e.g., the electrode 64 in FIG. 5A). The main acoustically active region can provide a main mode of the BAW device 50. The main acoustically active region can be the central part of the active region that is free from frame structures, such as the recessed frame structure 67 and the raised frame structure 68.

While the BAW device 50 includes the recessed frame structure 67 and the raised frame structure 68, other frame structures can alternatively or additionally be implemented. For example, a raised frame structure with multiple layers including a layer between an electrode of a BAW device and a piezoelectric layer can be implemented. As another example, a floating raised frame structure can be implemented. As one more example, a raised frame structure can be implemented without a recessed frame structure.

One or more metal layers 70 and 72 can connect an electrode of the BAW device 50 to one or more other BAW devices, one or more integrated passive devices, one or more other circuit elements, one or more signal ports, the like, or any suitable combination thereof. An adhesion layer 74 can be positioned between the metal layer 70 and an underlying layer to increase adhesion between the layers. The adhesion layer 74 can be a titanium layer, for example.

FIG. 5B is an example plan view of the BAW device 50 of FIG. 5A. The cross-sectional view of FIG. 5A can be along the line from A to A′ in FIG. 5B. In FIG. 5B, the frame region FRAME and the main acoustically active region MAIN are shown. As illustrated, the main acoustically active region MAIN can correspond be the majority of the area of the BAW device 50. The frame region FRAME includes the recessed frame structure 67 and the raised frame structure 68 of the BAW device 50 of FIG. 5A. FIG. 5B illustrates the BAW device 50 with a pentagon shape with curved sides in plan view. A BAW device in accordance with any suitable principles and advantages disclosed herein can have any other suitable shape in plan view, such as a semi-elliptical shape, a semi-circular shape, a circular shape, an ellipsoid shape, a quadrilateral shape, or a quadrilateral shape with curved sides. Other BAW devices disclosed herein can have any suitable shape in plan view, such as a pentagon shape with curved sides.

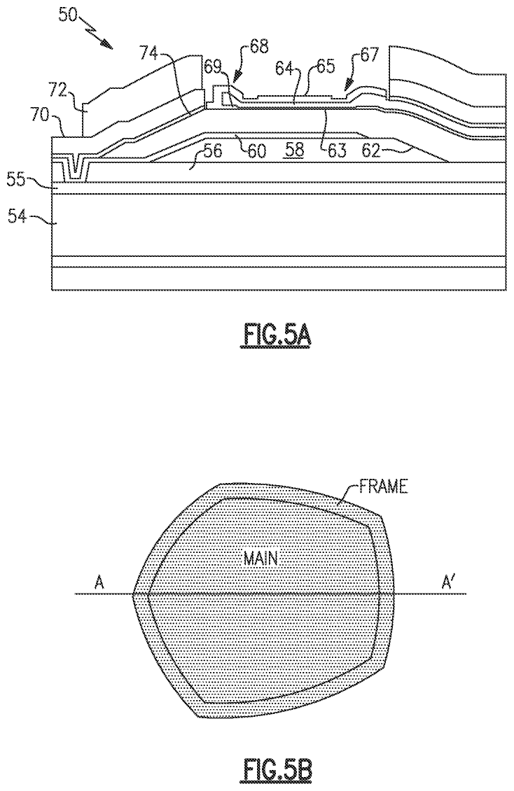

FIG. 6 is a cross-sectional diagram of a BAW device 80 according to an embodiment. The BAW device 80 includes a suspended raised frame structure 82 and an air bridge 84. Metal layer 86 is over the air bridge 84. The BAW device 80 can achieve one or more of a relatively high quality factor at anti-resonance (Qp), relatively low lateral spur, or relatively low non-linearity. An acoustic wave filter that includes one or more BAW devices 80 can achieve a relatively sharp filter skip and/or a relatively wide passband.

The BAW device 80 includes at least one amorphous silicon oxycarbide layer. A first passivation layer 56 of the BAW device 80 can be an amorphous silicon oxycarbide layer. As illustrated, the first passivation layer 56 is located over a trap rich layer 55. A second passivation layer 65 can be an amorphous silicon oxycarbide layer. The second passivation layer 65 can be used for both passivation and frequency trimming. The second passivation layer 65 can be included in a raised frame structure 68 and a recessed frame structure 67 of the BAW device 80. In some applications (not illustrated in FIG. 6), a temperature compensation layer can be included between an electrode (e.g., second electrode 64) and a piezoelectric layer 62 in a main acoustically active region of the BAW device 80. Such a temperature compensation layer can include amorphous silicon oxycarbide.

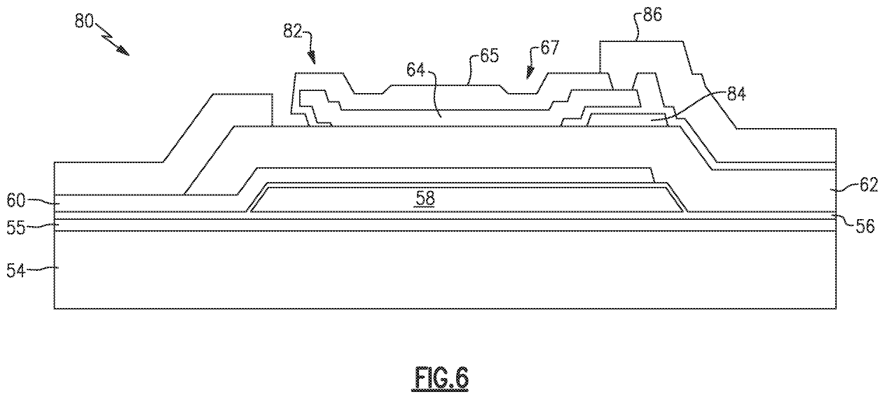

FIG. 7 is a cross-sectional view of a portion of a temperature compensated BAW (TCBAW) device 90 according to an embodiment. The TCBAW device 90 includes a temperature compensation layer 63 positioned between a piezoelectric layer 62 and a second electrode layer 64. As illustrated in FIG. 7, the temperature compensation layer 63 is in physical contact with the piezoelectric layer 62. The temperature compensation layer 63 can be in physical contact with the second electrode 64 as illustrated. The temperature compensation layer 63 can include amorphous silicon oxycarbide. The amorphous silicon oxycarbide can be doped with a suitable dopant. The amorphous silicon oxycarbide can include free carbon.

Passivation layers 65 and/or 91 of the TCBAW device 90 can include amorphous silicon oxycarbide in certain instances. The TCBAW device 90 can include a passivation layer over a trap rich layer in a portion of the TCBAW device 90 that is not illustrated in FIG. 7, where the passivation layer includes amorphous silicon oxycarbide. A raised frame structure of the BAW device 90 can include an oxide raised frame layer 92. The oxide raised frame layer 92 can include amorphous silicon oxycarbide and/or silicon dioxide. In some applications, the BAW device 90 includes electrodes 60 and 64 that include ruthenium and a piezoelectric layer 62 that includes aluminum nitride.

FIG. 8 is a cross-sectional view of a portion of a TCBAW device 95 according to an embodiment. The TBAW device 95 includes a temperature compensation layer 63 positioned between a piezoelectric layer 62 and a second electrode layer 64. The temperature compensation layer 63 can include amorphous silicon oxycarbide. The amorphous silicon oxycarbide can be doped with a suitable dopant. The amorphous silicon oxycarbide can include free carbon. Passivation layer 65 of the TCBAW device 95 can include amorphous silicon oxycarbide in certain instances. The TCBAW device 95 can include a passivation layer over a trap rich layer in a portion of the TCBAW 95 device that is not illustrated in FIG. 8, where the passivation layer includes amorphous silicon oxycarbide. The TCBAW device 95 also includes a raised frame structure that includes an oxide raised frame layer 96 and a metal raised frame layer 97. The raised frame structure can reduce lateral energy leakage from a main acoustically active region of the TCBAW device 95.

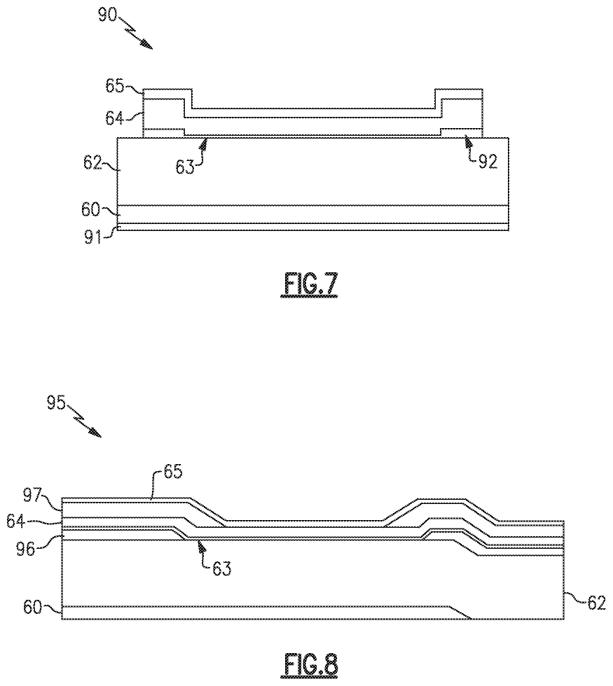

Acoustic wave devices disclosed herein can be implemented as acoustic wave resonators in a variety of filters. Such filters can be arranged to filter a radio frequency signal. Acoustic wave devices disclosed herein can be implemented in a variety of different filter topologies. Example filter topologies include without limitation, ladder filters, lattice filters, hybrid ladder lattice filters, notch filters where a notch is created by an acoustic wave resonator, hybrid acoustic and non-acoustic inductor-capacitor filters, and the like. The example filter topologies can implement band pass filters. The example filter topologies can implement band stop filters. In some instances, acoustic wave devices disclosed herein can be implemented in filters with one or more other types of resonators and/or with passive impedance elements, such as one or more inductors and/or one or more capacitors. An example filter topology will be discussed with reference to FIG. 9A.

FIG. 9A is a schematic diagram of a ladder filter 150 that includes an acoustic wave resonator according to an embodiment. The ladder filter 150 is an example topology that can implement a band pass filter formed of acoustic wave resonators. In a band pass filter with a ladder filter topology, the shunt resonators can have lower resonant frequencies than the series resonators. The ladder filter 150 can be arranged to filter a radio frequency signal. As illustrated, the ladder filter 150 includes series acoustic wave resonators R1 R3, R5, R7, and R9 and shunt acoustic wave resonators R2, R4, R6, and R8 coupled between a first input/output port I/O₁ and a second input/output port 1102. Any suitable number of series acoustic wave resonators can be in included in a ladder filter. Any suitable number of shunt acoustic wave resonators can be included in a ladder filter. The first input/output port I/O₁ can be a transmit port and the second input/output port I/O₂ can be an antenna port. Alternatively, first input/output port I/O₁ can be a receive port and the second input/output port I/O₂ can be an antenna port. One or more of the acoustic wave resonators of the ladder filter 150 can include an acoustic wave device including a silicon oxycarbide layer in accordance with any suitable principles and advantages disclosed herein. All acoustic resonators of the ladder filter 150 can include a silicon oxycarbide layer in accordance with any suitable principles and advantages disclosed herein in certain applications.

A filter that includes an acoustic wave resonator in accordance with any suitable principles and advantages disclosed herein be arranged to filter a radio frequency signal in a fifth generation 5G NR operating band within Frequency Range 1 (FR1). FR1 can be from 410 MHz to 7.125 gigahertz (GHz), for example, as specified in a current 5G NR specification. A filter that an acoustic wave resonator in accordance with any suitable principles and advantages disclosed herein can be arranged to filter a radio frequency signal in a fourth generation (4G) Long Term Evolution (LTE) operating band. A filter that includes an acoustic wave resonator in accordance with any suitable principles and advantages disclosed herein can be included in a filter having a passband that includes a 4G LTE operating band and a 5G NR operating band. Such a filter can be implemented in a dual connectivity application, such as an E-UTRAN New Radio—Dual Connectivity (ENDC) application. A multiplexer including any such filters can include one or more other filters with a passband corresponding to a 5G NR operating band and/or a 4G LTE operating band.

FIG. 9B is schematic diagram of an acoustic wave filter 160. The acoustic wave filter 160 can include the acoustic wave resonators of the ladder filter 150. The acoustic wave filter 160 is a band pass filter. The acoustic wave filter 160 is arranged to filter a radio frequency signal. The acoustic wave filter 160 includes one or more acoustic wave devices coupled between a first input/output port RF_IN and a second input/output port RF_OUT. The acoustic wave filter 160 includes an acoustic wave resonator according to an embodiment.

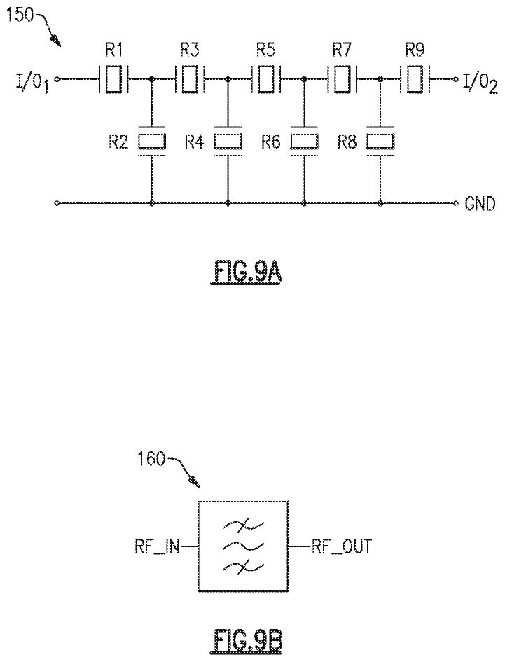

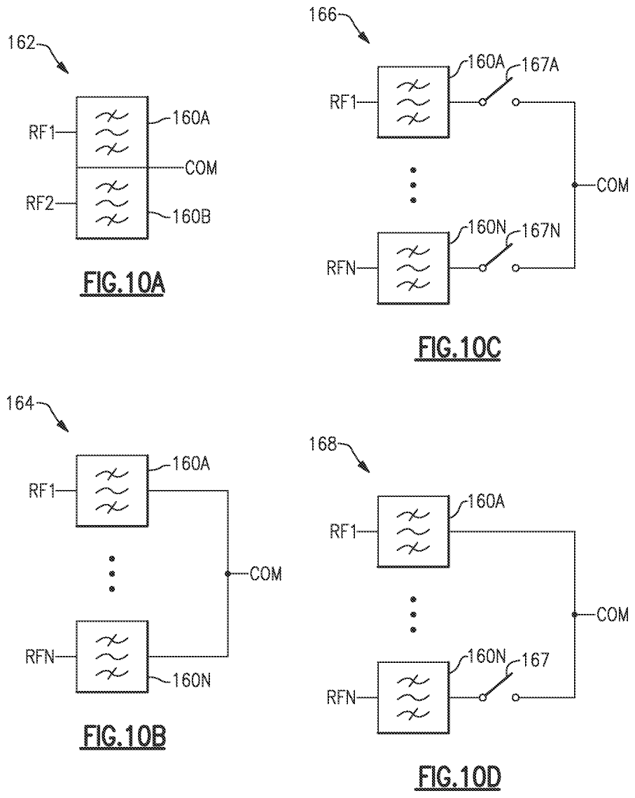

The acoustic wave devices disclosed herein can be implemented in a standalone filter and/or in a filter of any suitable multiplexer. Such filters can be any suitable topology, such as a ladder filter topology. The filter can be a band pass filter arranged to filter a 4G LTE band and/or 5G NR band. Example multiplexers will be discussed with reference to FIGS. 10A to 10D. Any suitable principles and advantages of these multiplexers can be implemented together with each other.

FIG. 10A is a schematic diagram of a duplexer 162 that includes an acoustic wave filter according to an embodiment. The duplexer 162 includes a first filter 160A and a second filter 160B coupled to together at a common node COM. One of the filters of the duplexer 162 can be a transmit filter and the other of the filters of the duplexer 162 can be a receive filter. In some other instances, such as in a diversity receive application, the duplexer 162 can include two receive filters. Alternatively, the duplexer 162 can include two transmit filters. The common node COM can be an antenna node.

The first filter 160A is an acoustic wave filter arranged to filter a radio frequency signal. The first filter 160A includes one or more acoustic wave resonators coupled between a first radio frequency node RF1 and the common node COM. The first radio frequency node RF1 can be a transmit node or a receive node. The first filter 160A includes an acoustic wave resonator in accordance with any suitable principles and advantages disclosed herein.

The second filter 160B can be any suitable filter arranged to filter a second radio frequency signal. The second filter 160B can be, for example, an acoustic wave filter, an acoustic wave filter that includes an acoustic wave resonator with at least one silicon oxycarbide layer, an LC filter, a hybrid acoustic wave LC filter, or the like. The second filter 160B is coupled between a second radio frequency node RF2 and the common node. The second radio frequency node RF2 can be a transmit node or a receive node.

Although example embodiments may be discussed with filters or duplexers for illustrative purposes, any suitable principles and advantages disclosed herein can be implement in a multiplexer that includes a plurality of filters coupled together at a common node. Examples of multiplexers include but are not limited to a duplexer with two filters coupled together at a common node, a triplexer with three filters coupled together at a common node, a quadplexer with four filters coupled together at a common node, a hexaplexer with six filters coupled together at a common node, an octoplexer with eight filters coupled together at a common node, or the like. Multiplexers can include filters having different passbands. Multiplexers can include any suitable number of transmit filters and any suitable number of receive filters. For example, a multiplexer can include all receive filters, all transmit filters, or one or more transmit filters and one or more receive filters. One or more filters of a multiplexer can include any suitable number of acoustic wave devices in accordance with any suitable principles and advantages disclosed herein.

FIG. 10B is a schematic diagram of a multiplexer 164 that includes an acoustic wave filter according to an embodiment. The multiplexer 164 includes a plurality of filters 160A to 160N coupled together at a common node COM. The plurality of filters can include any suitable number of filters including, for example, 3 filters, 4 filters, 5 filters, 6 filters, 7 filters, 8 filters, or more filters. Some or all of the plurality of acoustic wave filters can be acoustic wave filters. As illustrated, the filters 160A to 160N each have a fixed electrical connection to the common node COM. This can be referred to as hard multiplexing or fixed multiplexing. Filters have fixed electrical connections to the common node in hard multiplexing applications.

The first filter 160A is an acoustic wave filter arranged to filter a radio frequency signal. The first filter 160A can include one or more acoustic wave devices coupled between a first radio frequency node RF1 and the common node COM. The first radio frequency node RF1 can be a transmit node or a receive node. The first filter 160A includes an acoustic wave resonator in accordance with any suitable principles and advantages disclosed herein. The other filter(s) of the multiplexer 164 can include one or more acoustic wave filters, one or more acoustic wave filters that include an acoustic wave resonator in accordance with any suitable principles and advantages disclosed herein, one or more LC filters, one or more hybrid acoustic wave LC filters, the like, or any suitable combination thereof.

FIG. 10C is a schematic diagram of a multiplexer 166 that includes an acoustic wave filter according to an embodiment. The multiplexer 166 is like the multiplexer 164 of FIG. 10B, except that the multiplexer 166 implements switched multiplexing. In switched multiplexing, a filter is coupled to a common node via a switch. In the multiplexer 166, the switches 167A to 167N can selectively electrically connect respective filters 160A to 160N to the common node COM. For example, the switch 167A can selectively electrically connect the first filter 160A the common node COM via the switch 167A. Any suitable number of the switches 167A to 167N can electrically a respective filter 160A to 160N to the common node COM in a given state. Similarly, any suitable number of the switches 167A to 167N can electrically isolate a respective filter 160A to 160N to the common node COM in a given state. The functionality of the switches 167A to 167N can support various carrier aggregations.

FIG. 10D is a schematic diagram of a multiplexer 168 that includes an acoustic wave filter according to an embodiment. The multiplexer 168 illustrates that a multiplexer can include any suitable combination of hard multiplexed and switched multiplexed filters. One or more acoustic wave devices in accordance with any suitable principles and advantages disclosed herein can be included in a filter (e.g., the filter 160A) that is hard multiplexed to the common node COM of the multiplexer 168. Alternatively or additionally, one or more acoustic wave devices in accordance with any suitable principles and advantages disclosed herein can be included in a filter (e.g., the filter 160N) that is switch multiplexed to the common node COM of the multiplexer 168.

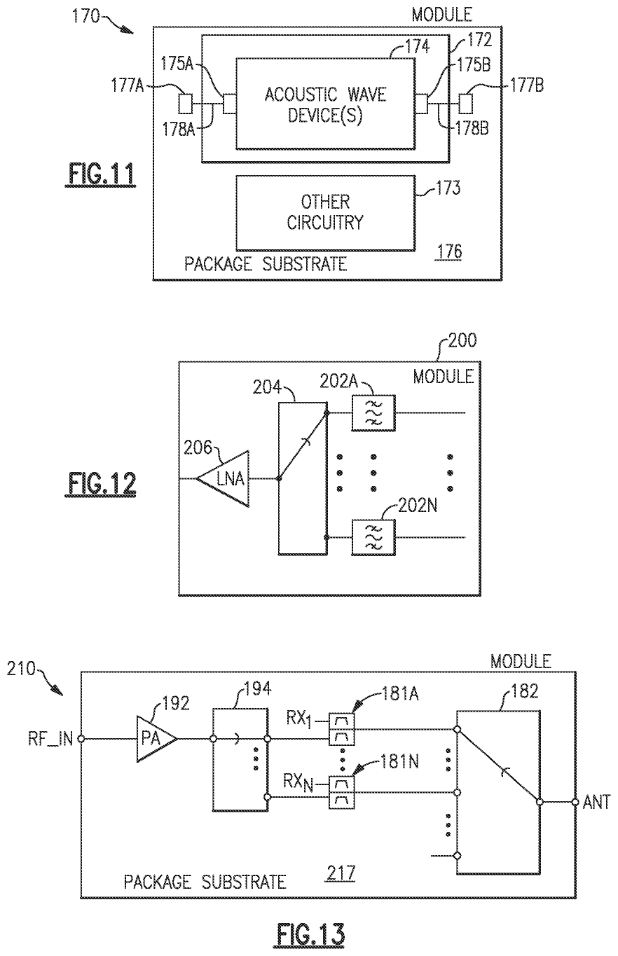

Acoustic wave devices disclosed herein can be implemented in a variety of packaged modules. Some example packaged modules will now be disclosed in which any suitable principles and advantages of the acoustic wave devices disclosed herein can be implemented. The example packaged modules can include a package that encloses the illustrated circuit elements. A module that includes a radio frequency component can be referred to as a radio frequency module. The illustrated circuit elements can be disposed on a common packaging substrate. The packaging substrate can be a laminate substrate, for example. FIGS. 11 to 13 are schematic block diagrams of illustrative packaged modules according to certain embodiments. Any suitable combination of features of these packaged modules can be implemented with each other.

FIG. 11 is a schematic diagram of a radio frequency module 170 that includes an acoustic wave component 172 according to an embodiment. The illustrated radio frequency module 170 includes the acoustic wave component 172 and other circuitry 173. The acoustic wave component 172 can include an acoustic wave filter that includes a plurality of acoustic wave devices, for example. The acoustic wave devices can be BAW devices in certain applications.

The acoustic wave component 172 shown in FIG. 11 includes one or more acoustic wave devices 174 and terminals 175A and 175B. The one or more acoustic wave devices 174 include at least one acoustic wave device implemented in accordance with any suitable principles and advantages disclosed herein. The terminals 175A and 174B can serve, for example, as an input contact and an output contact. Although two terminals are illustrated, any suitable number of terminals can be implemented for a particular application. The acoustic wave component 172 and the other circuitry 173 are on a common packaging substrate 176 in FIG. 11. The packaging substrate 176 can be a laminate substrate. The terminals 175A and 175B can be electrically connected to contacts 177A and 177B, respectively, on the packaging substrate 176 by way of electrical connectors 178A and 178B, respectively. The electrical connectors 178A and 178B can be bumps or wire bonds, for example.

The other circuitry 173 can include any suitable additional circuitry. For example, the other circuitry can include one or more radio frequency amplifiers (e.g., one or more power amplifiers and/or one or more low noise amplifiers), one or more radio frequency switches, one or more additional filters, one or more radio frequency (RF) couplers, one or more delay lines, one or more phase shifters, the like, or any suitable combination thereof. Accordingly, the other circuitry 173 can include one or more radio frequency circuit elements. The other circuitry 173 can be radio frequency circuitry. The other circuitry 173 can be electrically connected to the one or more acoustic wave devices 174. The radio frequency module 170 can include one or more packaging structures to, for example, provide protection and/or facilitate easier handling of the radio frequency module 170. Such a packaging structure can include an overmold structure formed over the packaging substrate 176. The overmold structure can encapsulate some or all of the components of the radio frequency module 170.

FIG. 12 is a schematic block diagram of a module 200 that includes filters 202A to 202N, a radio frequency switch 204, and a low noise amplifier 206 according to an embodiment. One or more filters of the filters 202A to 202N can include any suitable number of acoustic wave devices in accordance with any suitable principles and advantages disclosed herein. Any suitable number of filters 202A to 202N can be implemented. The illustrated filters 202A to 202N are receive filters. One or more of the filters 202A to 202N can be included in a multiplexer that also includes a transmit filter and/or another receive filter. The radio frequency switch 204 can be a multi-throw radio frequency switch. The radio frequency switch 204 can electrically couple an output of a selected filter of filters 202A to 202N to the low noise amplifier 206. In some embodiments, a plurality of low noise amplifiers can be implemented. The module 200 can include diversity receive features in certain applications.

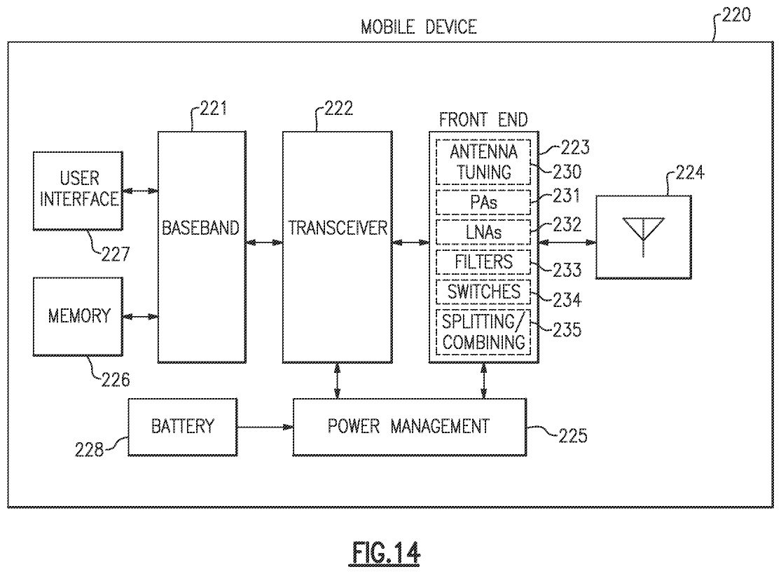

FIG. 13 is a schematic diagram of a radio frequency module 210 that includes an acoustic wave filter according to an embodiment. As illustrated, the radio frequency module 210 includes duplexers 181A to 181N, a power amplifier 192, a radio frequency switch 194 configured as a select switch, and an antenna switch 182. The radio frequency module 210 can include a package that encloses the illustrated elements. The illustrated elements can be disposed on a common packaging substrate 217. The packaging substrate 217 can be a laminate substrate, for example. A radio frequency module that includes a power amplifier can be referred to as a power amplifier module. A radio frequency module can include a subset of the elements illustrated in FIG. 13 and/or additional elements. The radio frequency module 210 may include any one of the acoustic wave filters that include at least one acoustic wave resonator in accordance with any suitable principles and advantages disclosed herein.

The duplexers 181A to 181N can each include two acoustic wave filters coupled to a common node. For example, the two acoustic wave filters can be a transmit filter and a receive filter. As illustrated, the transmit filter and the receive filter can each be a band pass filter arranged to filter a radio frequency signal. One or more of the transmit filters can include an acoustic wave device in accordance with any suitable principles and advantages disclosed herein. Similarly, one or more of the receive filters can include an acoustic wave device in accordance with any suitable principles and advantages disclosed herein. Although FIG. 13 illustrates duplexers, any suitable principles and advantages disclosed herein can be implemented in other multiplexers (e.g., quadplexers, hexaplexers, octoplexers, etc.) and/or in switched multiplexers and/or with standalone filters.

The power amplifier 192 can amplify a radio frequency signal. The illustrated radio frequency switch 194 is a multi-throw radio frequency switch. The radio frequency switch 194 can electrically couple an output of the power amplifier 192 to a selected transmit filter of the transmit filters of the duplexers 181A to 181N. In some instances, the radio frequency switch 194 can electrically connect the output of the power amplifier 192 to more than one of the transmit filters. The antenna switch 182 can selectively couple a signal from one or more of the duplexers 181A to 181N to an antenna port ANT. The duplexers 181A to 181N can be associated with different frequency bands and/or different modes of operation (e.g., different power modes, different signaling modes, etc.).

The acoustic wave devices disclosed herein can be implemented in wireless communication devices. FIG. 14 is a schematic block diagram of a wireless communication device 220 that includes an acoustic wave device according to an embodiment. The wireless communication device 220 can be a mobile device. The wireless communication device 220 can be any suitable wireless communication device. For instance, a wireless communication device 220 can be a mobile phone, such as a smart phone. As illustrated, the wireless communication device 220 includes a baseband system 221, a transceiver 222, a front end system 223, one or more antennas 224, a power management system 225, a memory 226, a user interface 227, and a battery 228.

The wireless communication device 220 can be used communicate using a wide variety of communications technologies, including, but not limited to, 2G, 3G, 4G (including LTE, LTE-Advanced, and/or LTE-Advanced Pro), 5G NR, WLAN (for instance, Wi-Fi), WPAN (for instance, Bluetooth and/or ZigBee), WMAN (for instance, WiMax), and/or GPS technologies.

The transceiver 222 generates RF signals for transmission and processes incoming RF signals received from the antennas 224. Various functionalities associated with the transmission and receiving of RF signals can be achieved by one or more components that are collectively represented in FIG. 14 as the transceiver 222. In one example, separate components (for instance, separate circuits or dies) can be provided for handling certain types of RF signals.

The front end system 223 aids in conditioning signals provided to and/or received from the antennas 224. In the illustrated embodiment, the front end system 223 includes antenna tuning circuitry 230, power amplifiers (PAs) 231, low noise amplifiers (LNAs) 232, filters 233, switches 234, and signal splitting/combining circuitry 235. However, other implementations are possible. The filters 233 can include one or more acoustic wave filters that include any suitable number of acoustic wave devices in accordance with any suitable principles and advantages disclosed herein.

For example, the front end system 223 can provide a number of functionalities, including, but not limited to, amplifying signals for transmission, amplifying received signals, filtering signals, switching between different bands, switching between different power modes, switching between transmission and receiving modes, duplexing of signals, multiplexing of signals, or any suitable combination thereof.

In certain implementations, the wireless communication device 220 supports carrier aggregation, thereby providing flexibility to increase peak data rates. Carrier aggregation can be used for Frequency Division Duplexing (FDD) and/or Time Division Duplexing (TDD), and may be used to aggregate a plurality of carriers and/or channels. Carrier aggregation includes contiguous aggregation, in which contiguous carriers within the same operating frequency band are aggregated. Carrier aggregation can also be non-contiguous, and can include carriers separated in frequency within a common band or in different bands.

The antennas 224 can include antennas used for a wide variety of types of communications. For example, the antennas 224 can include antennas for transmitting and/or receiving signals associated with a wide variety of frequencies and communications standards.

In certain implementations, the antennas 224 support MIMO communications and/or switched diversity communications. For example, MIMO communications use multiple antennas for communicating multiple data streams over a single radio frequency channel. MIMO communications benefit from higher signal to noise ratio, improved coding, and/or reduced signal interference due to spatial multiplexing differences of the radio environment. Switched diversity refers to communications in which a particular antenna is selected for operation at a particular time. For example, a switch can be used to select a particular antenna from a group of antennas based on a variety of factors, such as an observed bit error rate and/or a signal strength indicator.

The wireless communication device 220 can operate with beamforming in certain implementations. For example, the front end system 223 can include amplifiers having controllable gain and phase shifters having controllable phase to provide beam formation and directivity for transmission and/or reception of signals using the antennas 224. For example, in the context of signal transmission, the amplitude and phases of the transmit signals provided to the antennas 224 are controlled such that radiated signals from the antennas 224 combine using constructive and destructive interference to generate an aggregate transmit signal exhibiting beam-like qualities with more signal strength propagating in a given direction. In the context of signal reception, the amplitude and phases are controlled such that more signal energy is received when the signal is arriving to the antennas 224 from a particular direction. In certain implementations, the antennas 224 include one or more arrays of antenna elements to enhance beamforming.

The baseband system 221 is coupled to the user interface 227 to facilitate processing of various user input and output (I/O), such as voice and data. The baseband system 221 provides the transceiver 222 with digital representations of transmit signals, which the transceiver 222 processes to generate RF signals for transmission. The baseband system 221 also processes digital representations of received signals provided by the transceiver 222. As shown in FIG. 14, the baseband system 221 is coupled to the memory 226 of facilitate operation of the wireless communication device 220.

The memory 226 can be used for a wide variety of purposes, such as storing data and/or instructions to facilitate the operation of the wireless communication device 220 and/or to provide storage of user information.

The power management system 225 provides a number of power management functions of the wireless communication device 220. In certain implementations, the power management system 225 includes a PA supply control circuit that controls the supply voltages of the power amplifiers 231. For example, the power management system 225 can be configured to change the supply voltage(s) provided to one or more of the power amplifiers 231 to improve efficiency, such as power added efficiency (PAE).

As shown in FIG. 14, the power management system 225 receives a battery voltage from the battery 228. The battery 228 can be any suitable battery for use in the wireless communication device 220, including, for example, a lithium-ion battery.

Any of the embodiments described above can be implemented in association with mobile devices such as cellular handsets. The principles and advantages of the embodiments can be used for any systems or apparatus, such as any uplink wireless communication device, that could benefit from any of the embodiments described herein. The teachings herein are applicable to a variety of systems. Although this disclosure includes example embodiments, the teachings described herein can be applied to a variety of structures. Any of the principles and advantages discussed herein can be implemented in association with RF circuits configured to process signals having a frequency in a range from about 30 kHz to 300 GHz, such as in a frequency range from about 400 MHz to 8.5 GHz, in a frequency range from about 2 GHz to 10 GHz, or in a frequency range from 5 GHz to 20 GHz.

Aspects of this disclosure can be implemented in various electronic devices. Examples of the electronic devices can include, but are not limited to, consumer electronic products, parts of the consumer electronic products such as packaged radio frequency modules, uplink wireless communication devices, wireless communication infrastructure, electronic test equipment, etc. Examples of the electronic devices can include, but are not limited to, a mobile phone such as a smart phone, a wearable computing device such as a smart watch or an ear piece, a telephone, a television, a computer monitor, a computer, a modem, a hand-held computer, a laptop computer, a tablet computer, a microwave, a refrigerator, a vehicular electronics system such as an automotive electronics system, a robot such as an industrial robot, an Internet of things device, a stereo system, a digital music player, a radio, a camera such as a digital camera, a portable memory chip, a home appliance such as a washer or a dryer, a peripheral device, a wrist watch, a clock, etc. Further, the electronic devices can include unfinished products.

Unless the context indicates otherwise, throughout the description and the claims, the words “comprise,” “comprising,” “include,” “including” and the like are to generally be construed in an inclusive sense, as opposed to an exclusive or exhaustive sense; that is to say, in the sense of “including, but not limited to.” Conditional language used herein, such as, among others, “can,” “could,” “might,” “may,” “e.g.,” “for example,” “such as” and the like, unless specifically stated otherwise, or otherwise understood within the context as used, is generally intended to convey that certain embodiments include, while other embodiments do not include, certain features, elements and/or states. The word “coupled”, as generally used herein, refers to two or more elements that may be either directly connected, or connected by way of one or more intermediate elements. Likewise, the word “connected”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number respectively.

While certain embodiments have been described, these embodiments have been presented by way of example only, and are not intended to limit the scope of the disclosure. Indeed, the novel resonators, filters, multiplexer, devices, modules, wireless communication devices, apparatus, methods, and systems described herein may be embodied in a variety of other forms. Furthermore, various omissions, substitutions, and changes in the form of the resonators, filters, multiplexer, devices, modules, wireless communication devices, apparatus, methods, and systems described herein may be made without departing from the spirit of the disclosure. For example, while blocks are presented in a given arrangement, alternative embodiments may perform similar functionalities with different components and/or circuit topologies, and some blocks may be deleted, moved, added, subdivided, combined, and/or modified. Each of these blocks may be implemented in a variety of different ways. Any suitable combination of the elements and/or acts of the various embodiments described above can be combined to provide further embodiments. The accompanying claims and their equivalents are intended to cover such forms or modifications as would fall within the scope and spirit of the disclosure.

What is claimed is:

1. An acoustic wave device with temperature compensation, the acoustic wave device comprising:
a piezoelectric layer;
an electrode; and
a temperature compensation layer including amorphous silicon oxycarbide, the temperature compensation layer in physical contact with at least a portion of the piezoelectric layer, and the acoustic wave device configured to generate an acoustic wave.

2. The acoustic wave device of claim 1 wherein the temperature compensation layer includes a dopant in the amorphous silicon oxycarbide.

3. The acoustic wave device of claim 1 wherein the amorphous silicon oxycarbide has a stoichiometric formula of SiO_{2(1-Z)}C_{Z} in which 0<Z<1.

4. The acoustic wave device of claim 1 wherein the amorphous silicon oxycarbide has a stoichiometric formula of SiO_{2(1-Z)}C_{Z}+yC_{free} in which 0<Z<1, 0<y<0.5, and C_{free} is elemental carbon.

5. The acoustic wave device of claim 1 wherein the electrode is an interdigital transducer electrode.

6. The acoustic wave device of claim 1 wherein the acoustic wave is a surface acoustic wave.

7. The acoustic wave device of claim 1 further comprising a support substrate under the piezoelectric layer.

8. The acoustic wave device of claim 1 further comprising a second electrode, the piezoelectric layer positioned between the electrode and the second electrode, and the acoustic wave is a bulk acoustic wave.

9. The acoustic wave device of claim 8 wherein the temperature compensation layer is positioned between the electrode and the piezoelectric layer.

10. The acoustic wave device of claim 8 further comprising an air cavity, the acoustic wave device being a film bulk acoustic wave resonator.

11. An acoustic wave device comprising:
a piezoelectric layer;
an interdigital transducer electrode on the piezoelectric layer; and
an amorphous silicon oxycarbide layer, the acoustic wave device configured to generate an acoustic wave.

12. The acoustic wave device of claim 11 wherein the amorphous silicon oxycarbide layer includes a dopant.

13. The acoustic wave device of claim 11 wherein material of the amorphous silicon oxycarbide has a stoichiometric formula of SiO_{2(1-Z)}C_{Z} in which 0<Z<1.

14. The acoustic wave device of claim 11 wherein material of the amorphous silicon oxycarbide has a stoichiometric formula of SiO_{2(1-Z)}C_{Z}+yC_{free} in which 0<Z<1, 0<y<0.5, and C_{free} is elemental carbon.

15. The acoustic wave device of claim 11 wherein the amorphous silicon oxycarbide layer is positioned over and in physical contact with the interdigital transducer electrode.

16. The acoustic wave device of claim 11 further comprising a support substrate, the amorphous silicon oxycarbide layer being positioned between the piezoelectric layer and the support substrate.

17. The acoustic wave device of claim 16 wherein the amorphous silicon oxycarbide layer is in physical contact with the piezoelectric layer.

18. The acoustic wave device of claim 16 further comprising an intervening layer positioned between the support substrate and the amorphous silicon oxycarbide layer.

19. The acoustic wave device of claim 16 further comprising a second amorphous silicon oxycarbide layer positioned over and in physical contact with the interdigital transducer electrode.

20. A radio frequency module comprising:
an acoustic wave filter including an acoustic wave device that includes a piezoelectric layer, an interdigital transducer electrode, and a temperature compensation layer including amorphous silicon oxycarbide, the acoustic wave filter configured to filter a radio frequency signal; and
radio frequency circuitry coupled to the acoustic wave filter, the acoustic wave filter and the radio frequency circuitry being enclosed within a common package.
